(19) United States
(12) Patent Application Publication
(10) Pub. No.: US 2015/0181756 A1
(43) Pub. Date: Jun. 25, 2015

(54) COOLING DEVICE, ELECTRIC AUTOMOBILE AND ELECTRONIC DEVICE EQUIPPED WITH SAID COOLING DEVICE

(71) Applicant: PANASONIC INTELLECTUAL PROPERTY MANAGEMENT CO. LTD., Osaka (JP)

(72) Inventors: Kaoru Sato, Aichi (JP); Wakana Nogami, Aichi (JP)

(73) Assignee: Panasonic Intellectual Property Management Co., Ltd., Osaka (JP)

(21) Appl. No.: 14/415,137

(22) PCT Filed: Sep. 3, 2013
(86) PCT No.: PCT/JP2013/005190

§ 371 Date: Jan. 15, 2015

(30) Foreign Application Priority Data
Sep. 5, 2012 (JP) 2012-194651
Dec. 7, 2012 (JP) 2012-267936
Mar. 27, 2013 (JP) 2013-065899

(51) Int. Cl. H05K 7/20; F25B 29/00

(52) U.S. Cl. CPC H05K 7/2029; F25B 29/00

(57) ABSTRACT

In cooling device, refrigerant is circulated through heat receiving unit, heat radiation passage, heat radiation unit, return passage, and heat receiving unit, and cooling is performed by making use of a phase change between a liquid phase and a gaseous phase of refrigerant. Heat receiving unit is configured by placing in series a plurality of heat receivers each of which has inflow port and an outflow port. Check valve is provided on an inflow port side of heat receiver which is closest to return passage among the plurality of heat receivers.

### TECHNICAL FIELD

The present invention relates to a cooling device, an electric automobile equipped with the cooling device, and an electronic device.

### BACKGROUND ART

Conventionally, a cooling device for an electric automobile equipped with a power semiconductor is mounted on a power converter circuit. In the electric automobile, a motor which configures a drive power source is switched and driven by an inverter circuit which is a power converter circuit. In the inverter circuit, a plurality of power semiconductors represented by power transistors are used. During an operation of the inverter circuit, high current flows through the respective power semiconductors and hence, the power semiconductors are highly heated. Accordingly, it is necessary to simultaneously cool the plurality of power semiconductors.

On the other hand, also in an electronic computer of these days, to cope with the remarkable increase of an amount of information to be processed, a number of CPUs (Central Processing Units) are used in an electronic device. The CPUs are heat generating bodies and hence, simultaneous cooling of the CPUs has been considered as an important task to be solved.

For example, a cooling device disclosed in PTL 1 uses two water circulations. That is, PTL 1 proposes the cooling device which uses: a first loop which transfers heat from respective electronic devices to respective heat exchanging parts; and a second loop which connects a plurality of heat exchanging parts in series.

However, in the cooling device which includes a plurality of heat receivers (heat exchanging parts) in one water circulating system such as the second loop, a contact point temperature of a surface of each heat receiver (each heat exchanging part) with a heat generating element is decided based on heat receiving performance of each heat receiver and a temperature of water which flows into the heat receiver. A contact point temperature of a surface of the last heat receiver with a heat generating element is a value obtained by adding an elevation temperature decided based on heat receiving performance of the heat receiver and a temperature of water discharged from the heat receiver of a preceding stage. Accordingly, there exists a first drawback that, in the plurality of heat receivers, the more latter stage the heat receiver is disposed, the higher a temperature of water which flows into the heat receiver becomes so that the more latter stage the heat receiver is disposed, the lower cooling performance of the cooling device becomes.

Further, in the cooling device disclosed in PTL 2, in a heat receiver disposed at a lower part of the cooling device, a refrigerant draws heat from a power semiconductor, and is vaporized. Then, the refrigerant is cooled and liquefied in a radiation part disposed at an upper part of the cooling device, and the refrigerant again drops on the lower part of the cooling device. This cycle is repeated and, as a result, an inverter circuit is cooled.

However, such a cooling device is of a boiling cooling type where a refrigerant is vaporized by being boiled by the heat receiver. In this boiling-cooling-type cooling device, the refrigerant receives heat in a state where a refrigerant stagnates in the heat receiver and hence, heat transfer efficiency to the refrigerant is poor so that the cooling device exhibits low cooling performance.

To the contrary, in a cooling device of a refrigerant circulation cooling type disclosed in PTL 3, a refrigerant receives heat in a heat receiver in a state where the refrigerant is in a convection state and hence, the heat transfer efficiency to a refrigerant is high so that cooling performance is remarkably enhanced. The cooling device disclosed in PTL 3 includes: a heat receiver; a heat radiation unit connected to a discharge port of the heat receiver by way of a heat radiation passage; a return passage connecting the heat radiation unit and an inflow port of the heat receiver; and a check valve disposed in the return passage.

An end of the return passage forms a projecting portion and projects into the inside of the heat radiation unit. In the projecting portion, a refrigerant is rapidly spread in a thin film state in the heat receiver. To be more specific, when a refrigerant which returns from the return circuit flows into the inside of the heat receiver due to opening of the check valve, a part of the refrigerant rapidly evaporates in the projecting portion of the return passage. A refrigerant remaining in the projecting portion is rapidly spread into the inside of the heat receiver in a thin film state by an evaporation pressure.

As a result, an extremely effective reception of heat is conducted on a surface of an inner wall of the heat receiver (a surface of a heat receiving plate) and hence, cooling performance of the cooling device is remarkably enhanced. Although the cooling device of a refrigerant circulation cooling type can remarkably enhance the cooling performance in this manner, it is necessary to further improve the mounting of the cooling device to various devices.

One of such improvement is that when the end of the return passage is projected into the inside of the heat receiver, the position of the end of the return passage in the heat receiver cannot be visually recognized. Accordingly, there exists a second drawback that the adjustment of the position of the end of the return passage takes time and efforts.

Further, there has been a demand for making an electric automobile and an electronic device compact and hence, it is necessary for a cooling device of a refrigerant circulation cooling type to lower a height thereof. However, in the cooling device of a refrigerant circulation cooling type disclosed in PTL 3 described above, to release the check valve, it is necessary to set a pressure on an upstream side of the check valve (return passage side) higher than a pressure on a downstream side of the check valve (heat receiver passage side). Accordingly, it is necessary for the return passage to ensure a certain height and hence, there exists a third drawback that the lowering of the height of the cooling device of a refrigerant circulation cooling type is difficult.

### CITATION LIST

### Patent Literatures

PTL 1: Unexamined Japanese Patent Publication No. 2005-222443

PTL 2: Unexamined Japanese Patent Publication No. 8-126125

PTL 3: Unexamined Japanese Patent Publication No. 2009-88127

### SUMMARY OF THE INVENTION

To overcome the first drawback, the cooling device according to the present invention includes: a heat receiving unit which absorbs heat generated by a heat generating element and transfers the heat generated by the heat generating element to a refrigerant; a heat radiation unit which radiates the heat of the refrigerant; and a heat radiation passage and a return passage which connect the heat receiving unit and the heat radiation unit. The cooling device performs cooling by making use of a phase change between a liquid phase and a gaseous phase of the refrigerant by circulating the refrigerant through the heat receiving unit, the heat radiation passage, the heat radiation unit, the return passage, and the heat receiving unit. The heat receiving unit is configured by placing in series a plurality of heat receivers each of which has an inflow port and an outflow port for the refrigerant. A check valve is provided on an inflow port side of the heat receiver which is closest to the return passage among the plurality of heat receivers.

In such a cooling device, the check valve is provided on the inflow port side of the heat receiver which is closest to the return passage among the plurality of heat receivers and hence, the plurality of heat receivers and the inside of the heat radiation passage form one communication space. That is, in the plurality of heat receivers and the inside of the heat radiation passage, a saturated vapor pressure of a refrigerant and a saturated vapor temperature take constant values. Accordingly, the plurality of heat receivers can transfer heat from the heat generating element to the refrigerant under predetermined conditions. As a result, each heat receiver can ensure the predetermined cooling performance and hence, it is possible to overcome the drawback that the more latter stage the heat receiver is disposed, the lower cooling performance of the cooling device becomes.

Further, to overcome the second drawback, the cooling device of the present invention includes: a heat receiver having an inflow port and a discharge port; a heat radiation unit connected to the discharge port by way of a heat radiation passage; a return passage which connects the heat radiation unit and the inflow port; and a check valve disposed in the return passage. The heat receiver includes: a heat receiving plate having a heat absorbing portion on a back surface side, the heat absorbing portion being in contact with a heat generating element for absorbing heat; and a heat receiving plate cover which covers a front surface side of the heat receiving plate with a gap formed therebetween. A narrow opening forming portion which lies close to a heat receiving plate is provided between the discharge port and the inflow port of the heat receiving plate cover. The heat absorbing portion is disposed on a discharge port side and an inflow port side with the narrow opening forming portion interposed therebetween.

Such a cooling device includes the narrow opening forming portion and hence, a flow speed of the refrigerant is increased when the refrigerant passes through the narrow opening forming portion and hence, the refrigerant is formed into a thin film shape. Accordingly, it becomes unnecessary to extend the end of the return passage to the inside of the heat receiver and it is also unnecessary to adjust the position of an end of the return passage.

Still further, to overcome the third drawback, the cooling device of the present invention includes: a heat receiver having an inflow port and a discharge port; a heat radiation unit having an inflow portion and an outflow portion; a heat radiation passage which connects the discharge port and the inflow portion; a return passage which connects the outflow portion and the inflow port; and a check valve disposed in the return passage. The inflow portion is disposed above the outflow portion. A discharge-port connection pipe passage of the heat radiation passage which is connected to the discharge port has a larger cross-sectional area than an inflow-port connection pipe passage of the return passage which is connected to the inflow port.

In such a cooling device, the discharge-port connection pipe passage has a larger cross-sectional area than a cross-sectional area of an inflow-port connection pipe passage and hence, a pressure in the heat receiver becomes small faster. As a result, even when a head pressure of a refrigerant in a liquid form accumulated in the return passage is low, the check valve is released. That is, a required length of the return passage above the check valve for applying a head pressure to the check valve becomes short and hence, the lowering of a height of the cooling device can be realized.

### BRIEF DESCRIPTION OF DRAWINGS

FIG. 1 is a schematic view of an electric automobile equipped with a cooling device according to a first exemplary embodiment of the present invention.

FIG. 2A is a plan view of the cooling device in a different configuration.

FIG. 2B is a front view of the cooling device shown in FIG. 2A.

FIG. 3A is a plan view of a heat receiver having low heat generation density of the cooling device according to the first exemplary embodiment of the present invention.

FIG. 3B is a front view of the heat receiver shown in FIG. 3A.

FIG. 3C is a side view of the heat receiver shown in FIG. 3A.

FIG. 4A is a plan view of another heat receiver having low heat generation density of the cooling device according to the first exemplary embodiment of the present invention.

FIG. 4B is a front view of the heat receiver shown in FIG. 4A.

FIG. 4C is a side view of the heat receiver shown in FIG. 4A.

FIG. 5A is a plan view of still another heat receiver having low heat generation density of the cooling device according to the first exemplary embodiment of the present invention.

FIG. 5B is a front view of the heat receiver shown in FIG. 5A.

FIG. 5C is a side view of the heat receiver shown in FIG. 5A.

FIG. 6A is a plan view showing a heat receiver having high heat generation density of the cooling device according to the first exemplary embodiment of the present invention.

FIG. 6B is a cross-sectional view taken along line 6B-6B in FIG. 6A.

FIG. 7A is a plan view showing another heat receiver having high heat generation density of the cooling device according to the first exemplary embodiment of the present invention.

FIG. 7B is a cross-sectional view taken along line 7B-7B in FIG. 7A.

FIG. 8A is a plan view of the heat receiver relevant to the cooling device according to the first exemplary embodiment of the present invention.

FIG. 8B is a front view of the heat receiver relating to the cooling device.

FIG. 8C is a graph showing a state of an operation temperature on a surface of the heat receiver relating to the cooling device.

FIG. 9 is a schematic view of an electronic device according to the first exemplary embodiment of the present invention.

FIG. 10 is a schematic view of an electric automobile according to a second exemplary embodiment of the present invention.

FIG. 11 is a front view showing a heat receiver of the cooling device.

FIG. 12 is a plan view showing the heat receiver of the cooling device.

FIG. 13 is a side view showing the heat receiver of the cooling device.

FIG. 14 is a schematic view of an electronic device according to the second exemplary embodiment of the present invention.

FIG. 15 is a schematic view of an electric automobile according to a third exemplary embodiment of the present invention.

FIG. 16A is a plan view showing the first configuration of the cooling device.

FIG. 16B is a front view of the cooling device shown in FIG. 16A.

FIG. 16C is a side view of the cooling device shown in FIG. 16A.

FIG. 17A is a plan view showing a first heat radiation passage of the cooling device according to the third exemplary embodiment of the present invention.

FIG. 17B is a plan view showing a second heat radiation passage of the cooling device.

FIG. 18A is a plan view showing a third heat radiation passage of the cooling device.

FIG. 18B is a plan view showing a fourth heat radiation passage of the cooling device.

FIG. 19A is a plan view showing a fifth heat radiation passage of the cooling device.

FIG. 19B is a plan view showing a sixth heat radiation passage of the cooling device.

FIG. 20A is a front view showing a second configuration of the cooling device.

FIG. 20B is a view showing an essential part of the heat radiation passage shown in FIG. 20A.

FIG. 21A is a plan view showing a third configuration of the cooling device according to the third exemplary embodiment of the present invention.

FIG. 21B is a front view of the cooling device shown in FIG. 21A.

FIG. 21C is a side view of the cooling device shown in FIG. 21A.

FIG. 22A is a plan view showing a fourth configuration of the cooling device according to the third exemplary embodiment of the present invention.

FIG. 22B is a front view of the cooling device shown in FIG. 22A.

FIG. 22C is a side view of the cooling device shown in FIG. 22A.

FIG. 23 is a schematic view of an electronic device according to the third exemplary embodiment of the present invention.

### DESCRIPTION OF EMBODIMENTS

Hereinafter, exemplary embodiments of the present invention are described with reference to the drawings.

### First Exemplary Embodiment

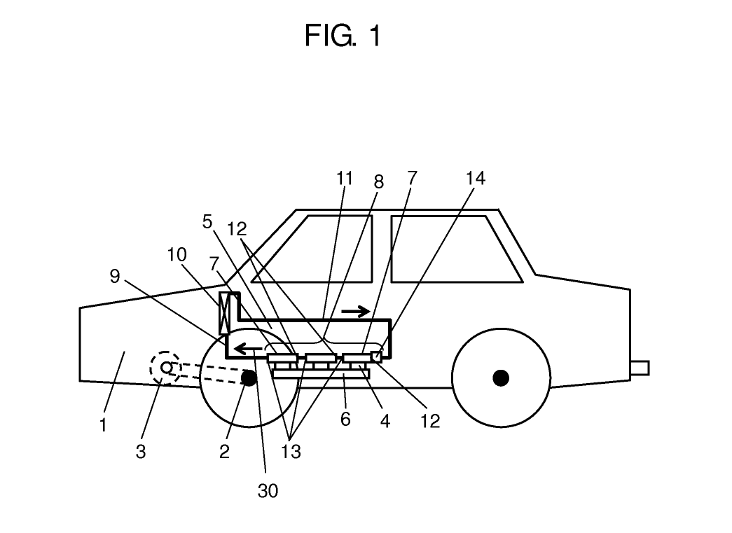

FIG. 1 is a schematic view of an electric automobile equipped with a cooling device according to a first exemplary embodiment of the present invention. As shown in FIG. 1, motor 3 which drives axle 2 of electric automobile 1 is connected to power converter 6 that is disposed in an electric automobile 1, and has a plurality of heat generating elements 4. Power converter 6 supplies power to motor 3.

Cooling device 5 which cools heat generating elements 4 is provided to power converter 6. Cooling device 5 includes: heat receiving unit 8; heat radiation unit 10; heat radiation passage 9; and return passage 11. Refrigerant 30 circulates through heat receiving unit 8, heat radiation passage 9, heat radiation unit 10, return passage 11, and heat receiving unit 8. Cooling device 5 performs cooling of heat generating elements 4 by making use of a phase change between a liquid phase and a gaseous phase of refrigerant 30. In this exemplary embodiment, heat receiving unit 8 absorbs heat generated by heat generating elements 4, and transfers the heat generated by heat generating elements 4 to refrigerant 30. Heat radiation unit 10 radiates the heat of refrigerant 30. Heat radiation passage 9 and return passage 11 are formed of pipe passages which connect heat receiving unit 8 and heat radiation unit 10 respectively.

Heat receiving unit 8 is configured by placing in series a plurality of heat receivers 7 each of which has inflow port 12 for refrigerant 30 and outflow port 13 for refrigerant 30. Check valve 14 is provided on an inflow port 12 side of heat receiver 7 which is closest to return passage 11 among the plurality of heat receivers 7.

A refrigerant circulation passage of cooling device 5 is of a closed system which is made up of heat receiving unit 8, heat radiation passage 9, heat radiation unit 10, return passage 11, and check valve 14. When water is used as a refrigerant, for example, in many cases, cooling device 5 is used in a state where an internal atmosphere of the refrigerant circulation passage is held at a negative pressure which is lower than an atmospheric pressure. An amount of water sealed in the refrigerant circulation passage is approximately several hundred cc (the amount being sufficiently smaller than a total volume of the circulation passage although the amount depends on a total volume of the circulation passage).

In cooling device 5 of the first exemplary embodiment having such a configuration, when a refrigerant sealed in heat receivers 7 is vaporized (changes phase) by making use of heat generated by heat generating elements 4, the refrigerant draws a large amount of latent heat. Further, a refrigerant flow at a high speed is always formed on a vaporizing surface due to a rapid change in volume at the time of vaporization and hence, cooling device 5 can realize extremely high cooling performance which allows cooling device 5 to cope with cooling of large capacity.

In cooling device 5 according to the first exemplary embodiment of the present invention, check valve 14 is provided to heat receiver 7 disposed on the most upstream side. Accordingly, the circulation direction of refrigerant 30 is determined. A volume of refrigerant 30 is expanded when refrigerant 30 which receives heat generated by heat generating elements 4 vaporizes in heat receiver 7. Due to such volume expansion of refrigerant 30 at the time of vaporization, refrigerant 30 is made to flow to heat radiation unit 10 at a high speed. As a result, a refrigerant driving force such as a pump which uses power becomes unnecessary in cooling device 5. In this manner, refrigerant 30 moves in a circulation passage at a high speed without using power and hence, an amount of refrigerant 30 which transfers heat per unit time is increased thus enhancing cooling performance of cooling device 5.

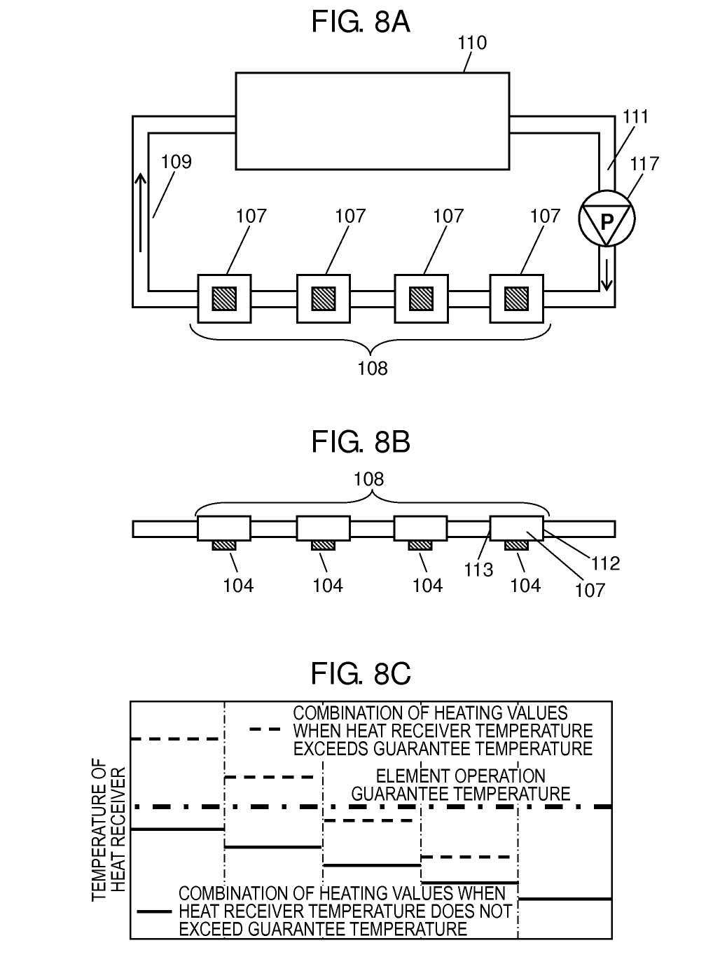

Further, as described above, a refrigerant driving force is generated by volume expansion of refrigerant 30 at the time of vaporization and hence, particular external power such as a water cooling pump is unnecessary whereby cooling device 5 according to the first exemplary embodiment possesses an extremely large advantageous effect in view of saving power. To compare cooling device 5 according to the first exemplary embodiment of the present invention with a cooling device which uses a water cooling pump, a description is made with reference to FIG. 8A to FIG. 8C. FIG. 8A is a plan view of the heat receiver relating to the cooling device according to the first exemplary embodiment of the present invention, FIG. 8B is a front view of the heat receiver relating to the cooling device, and FIG. 8C is a graph showing a state of an operation temperature on a surface of the heat receiver relating to the cooling device.

As shown in FIG. 8A, heat receiving unit 108 includes a plurality of heat receivers 107 which are connected to each other in series in a water circulation system. Heat radiation portion 110 is connected to both ends of heat receiving unit 108 by way of heat radiation passage 109 and return passage 111 respectively. Refrigerant driving pump 117 which drives a refrigerant is provided to an intermediate portion of return passage 111. For the sake of simplification of the description, assume that, in heat receiving unit 108 shown in FIG. 8B, heat receivers 107 have the same size and the same heating value, and heat generating elements 104 have the same size and the same heating value. Each heat receiver 107 has inflow port 112 and outflow port 113.

FIG. 8C is a graph showing a change in temperature at contact points between heat generating elements 104 and heat receivers 107. As shown in FIG. 8C, a temperature at each contact point between heat generating element 104 and heat receiver 107 is obtained by adding a temperature of refrigerant 30 which flows into heat receiver 107 from an upstream side and an amount of temperature elevated due to heat resistance of heat receiver 107. Accordingly, when a total heat quantity indicated by a solid line does not exceed an element operation guarantee temperature, cooling device 5 functions as a cooling device. However, when heating values of respective heat generating elements 104 become large so that a total heat quantity indicated by a broken line exceeds the element operation guarantee temperature in heat receivers 107 disposed on a downstream side, cooling device 5 cannot be used as a cooling device.

Accordingly, in the case of a water-cooling cooling device, when heat receivers 107 are connected in series, a heating value which can be loaded on respective heat receivers 107 is limited to a low value. To avoid such a situation to some extent, heat receivers 107 may be placed in parallel. However, when heat receivers 107 are placed in parallel, the number of pipes is increased so that the configuration of the cooling device becomes complicated as a whole. Accordingly, the parallel placement of heat receivers 107 is disadvantageous for making the device compact.

The fundamental difference between cooling device 5 according to the first exemplary embodiment of the present invention and the water-cooling cooling device lies in that the latter makes use of a change in water temperature due to sensible heat while the former makes use of latent heat which uses a phase change. For example, when water is used as a refrigerant, an amount of heat transfer per 1 g of latent heat is five or more times as large as an amount of heat transfer per 1 g of sensible heat and hence, the former can ensure higher cooling performance compared to the latter.

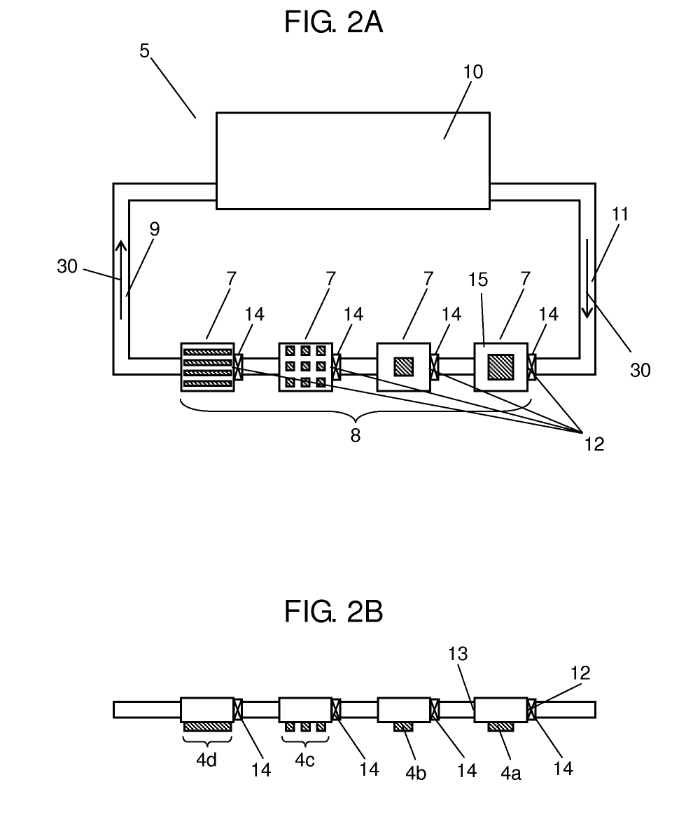

FIG. 2A is a plan view of the cooling device according to the first exemplary embodiment of the present invention in a different configuration, and FIG. 2B is a front view of the cooling device shown in FIG. 2A. As shown in FIG. 2A, in heat receiving unit 8, check valves 14 are provided on an inflow port 12 side of respective heat receivers 7 other than to heat receiver 7 which is closest to return passage 11 among the plurality of heat receivers 7. That is, check valves 14 are provided on the inflow port 12 side of all of the plurality of heat receivers 7 respectively.

The basic operation and advantageous effects of the cooling device shown in FIG. 2A are substantially equal to those of the cooling device shown in FIG. 8A. However, in the case where heat generating elements 4a, 4b, 4c, 4d shown in FIG. 2B have different heating values and the difference between the heating values is large, by mounting check valves 14 on respective heat receivers 7, an increase in pressure at the time of vaporization in each heat receiver 7 minimally influences other heat receivers 7 so that the cooling device 5 can easily ensure the stability in its operation.

When refrigerant 30 is vaporized on a surface of heat receiving plate 15, heat is drawn from heat receiving plate 15 as latent heat so that heat receiver 7 is cooled. A temperature at a contact point between heat receiver 7 and heat generating element 4 at this point of time is decided by a saturated vapor temperature of refrigerant 30 which is unequivocally determined by a saturated vapor pressure of refrigerant 30. That is, even when heat receiving unit 8 is made up of a plurality of heat receivers 7 and heat generating elements 4a, 4b, 4c, 4d having different heating values are mounted on respective heat receivers 7, an internal pressure in heat receiving unit 8 is a saturated vapor pressure generated due to the vaporization of refrigerant 30. Accordingly, respective heat receivers 7 have the substantially same pressure. The same phenomenon is observed in both the case where heat receivers 7 are connected in series and the case where heat receivers 7 are connected in parallel. However, by connecting heat receivers 7 in series, cooling device 5 can be made compact.

A saturated vapor pressure in each heat receiver 7 is determined by a total heat quantity of heat generating element 4 mounted on heat receiver 7. A temperature at the contact point between heat receiver 7 and heat generating element 4 is a value obtained by adding a temperature elevated due to a heating value and heat resistance of heat receiving plate 15 per se to a saturated vapor temperature. When heat receivers are connected in series in a conventional water cooling system, a temperature of water which flows out from the heat receiver on an upstream side becomes a temperature of water which flows into the heat receiver on a downstream side. Accordingly, the more the heat receiver is positioned on the downstream side, the higher a temperature at a contact point between the heat receiver and the heat generating element becomes. On the other hand, in cooling device 5 according to the first exemplary embodiment of the present invention which uses a phase change of refrigerant 30, a temperature at the contact point between heat receiver 7 and heat generating element 4 is determined based on a saturated vapor pressure. Accordingly, a temperature at a contact point between heat receiver 7 and heat generating element 4 on a downstream side is not influenced by a temperature of refrigerant 30 from an upstream side.

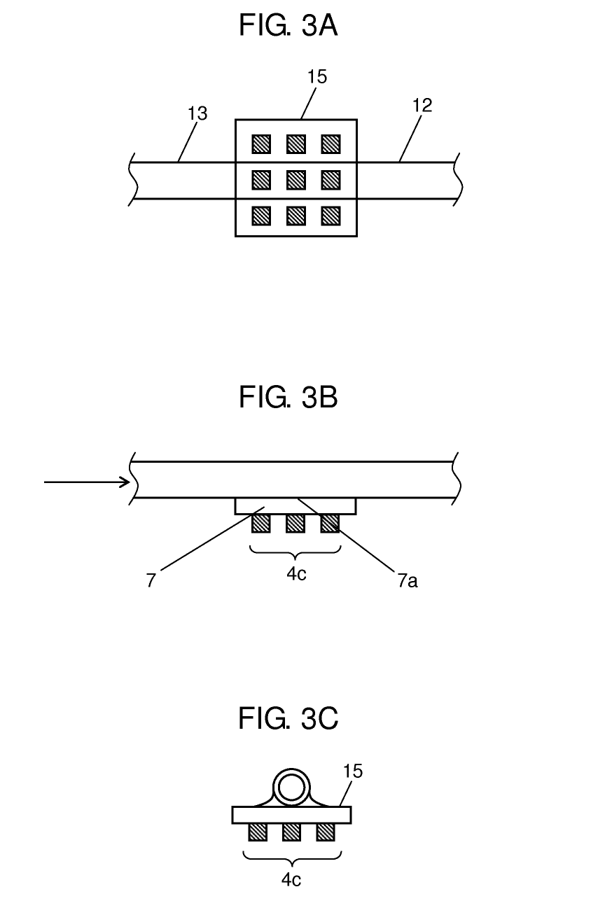

FIG. 3A is a plan view of a heat receiver having low heat generation density of the cooling device according to the first exemplary embodiment of the present invention, FIG. 3B is a front view of the heat receiver shown in FIG. 3A, and FIG. 3C is a side view of the heat receiver shown in FIG. 3A. FIG. 3A to FIG. 3C show a state where a pipe is joined to a heat generating element 4c having low heat generation density of less than 20 W/cm² and formed of nine scattered heat generating element portions as well as to heat receiving plate 15. When heat density of heat generating element 4c is less than 20 W/cm², tubular heat receiver 7a may be used as heat receiver 7. In heat receiver 7 shown in FIG. 3A to FIG. 3C, a cover is unnecessary for heat receiver 7 and hence, the number of parts is reduced whereby the configuration of the cooling device becomes simplified.

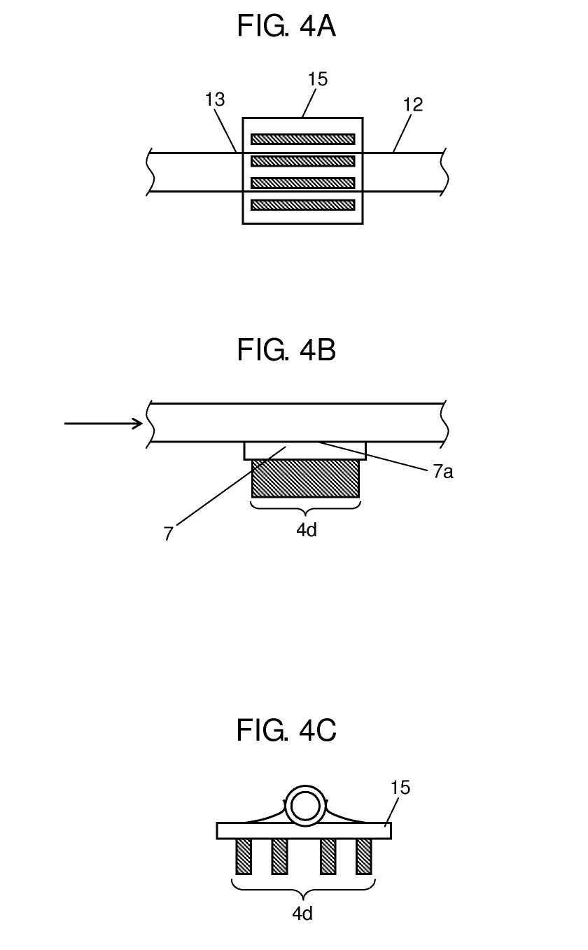

FIG. 4A is a plan view of another heat receiver having low heat generation density of the cooling device according to the first exemplary embodiment of the present invention, FIG. 4B is a front view of the heat receiver shown in FIG. 4A, and FIG. 4C is a side view of the heat receiver shown in FIG. 4A. FIG. 4A to FIG. 4C show a state where a pipe is joined to heat generating element 4d having low heat generation density and formed of four scattered strip-shaped heat generating element portions as well as to heat receiving plate 15. A cover of heat receiver 7 is also unnecessary for heat receiver 7 shown in FIG. 4A to FIG. 4C and hence, the number of parts is reduced whereby the configuration of the cooling device becomes simplified.

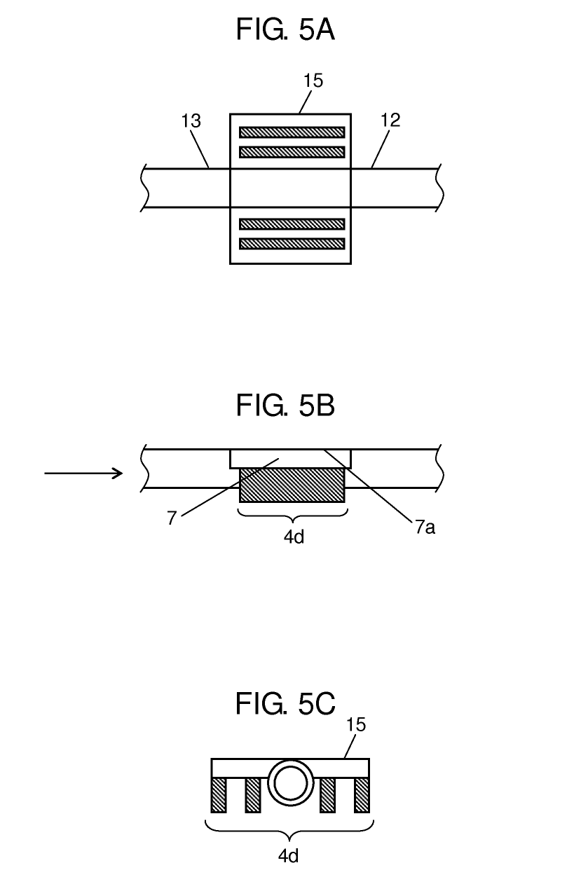

FIG. 5A is a plan view of still another heat receiver having low heat generation density of the cooling device according to the first exemplary embodiment of the present invention, FIG. 5B is a front view of the heat receiver shown in FIG. 5A, and FIG. 5C is a side view of the heat receiver shown in FIG. 5A. FIG. 5A to FIG. 5C show the configuration of the combination of strip-shaped heat generating element 4d having low heat generation density and formed of four scattered strip-shaped heat generating element portions as shown in FIG. 4A to FIG. 4C and heat receiving plate 15. The pipe is joined to a lower portion of heat receiving plate 15. In this configuration, a height of cooling device 5 shown in FIG. 2A becomes low as a whole, and a cooling effect of cooling device 5 is substantially equal to a cooling effect of cooling device 5 which uses heat receiver 7 shown in FIG. 3A to FIG. 3C.

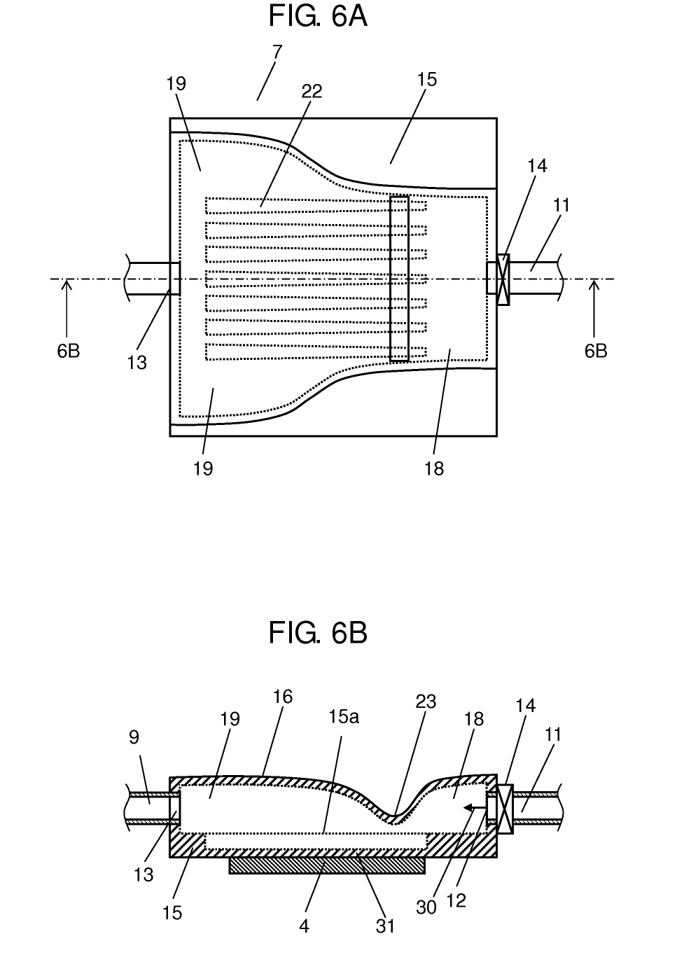

FIG. 6A is a plan view showing a heat receiver having high heat generation density of the cooling device according to the first exemplary embodiment of the present invention, and FIG. 6B is a cross-sectional view taken along line 6B-6B in FIG. 6A. As shown in FIG. 6A and FIG. 6B, inflow port 12 and outflow port 13 are respectively connected to both lateral surfaces of heat receiver 7.

As shown in FIG. 6A and FIG. 6B, heat receiver 7 includes heat receiving plate 15 and heat receiving plate cover 16 on a back surface side thereof. Narrow opening forming portion 23 which lies close to a heat receiving plate 15 side is disposed between outflow port 13 and inflow port 12 of heat receiving plate cover 16. In this exemplary embodiment, heat receiving plate 15 has heat absorbing portion 31 which absorbs heat by being in contact with heat generating element 4. Heat receiving plate cover 16 covers a vaporizing space for refrigerant 30 defined on surface side 15a of heat receiving plate 15. Outflow port 13 and inflow port 12 are formed in lateral wall surfaces of heat receiver 7.

By forming narrow opening forming portion 23 on heat receiving plate cover 16, in the inside of heat receiver 7, first space 18 is formed on an inflow port 12 side, and second space 19 is formed on an outflow port 13 side. First space 18 and second space 19 are connected to each other with narrow opening forming portion 23 interposed therebetween. First space 18 is smaller than second space 19.

Heat absorbing portion 31 of heat receiving plate 15 is disposed such that heat absorbing portion 31 is connected to an outflow port 13 side of narrow opening forming portion 23 and is also connected to an inflow port 12 side of narrow opening forming portion 23. Heat absorbing portion 31 is also formed such that an area of a portion of the heat absorbing portion 31 disposed on an outflow port 13 side from narrow opening forming portion 23 is set larger than an area of a portion of heat absorbing portion 31 disposed on the inflow port 12 side from narrow opening forming portion 23.

That is, when heat density of heat generating element 4 is 20 W/cm² or more, each of the plurality of heat receivers 7 includes heat receiving plate 15 having heat absorbing portion 31, and heat receiving plate cover 16 disposed on a front surface side 15a of heat receiving plate 15. Narrow opening forming portion 23 which reduces a cross section of a passage for refrigerant 30 is provided between outflow port 13 and inflow port 12. Heat absorbing portion 31 is disposed on an outflow port 13 side and an inflow port 12 side with narrow opening forming portion 23 interposed therebetween.

In the above-mentioned configuration, as shown in FIG. 6A and FIG. 6B, check valve 14 is connected to a portion of heat receiver 7 in the vicinity of inflow port 12. First space 18 formed in the inside of heat receiver 7 is smaller than second space 19 formed in the inside of heat receiver 7.

In an initial stage of operation of cooling device 5 shown in FIG. 2A, the inside of heat receiver 7 is filled with refrigerant 30. With heat generated by heat generating element 4, boiling of refrigerant 30 is started in first space 18 and in second space 19 substantially simultaneously. Since a first space 18 side is shut off by check valve 14, thereafter, refrigerant 30 in a gaseous phase and refrigerant 30 in a non-boiled liquid phase which are filled in first space 18 and in a second space 19 flow out to heat radiation passage 9 at a high speed and the flow of refrigerant 30 is started. Here, a force for driving which drives refrigerant 30 is the pressure difference between a pressure in heat receiver 7 and a pressure in heat radiation unit 10 which is cooled by outside air and is maintained at a low pressure.

At this stage of operation, firstly, refrigerant 30 filled in second space 19 flows out to heat radiation passage 9 formed in heat receiver 7. Refrigerant 30 filled in first space 18 is shut off by check valve 14 and hence, a part of refrigerant 30 is boiled. Due to the volume expansion at this point of time, refrigerant 30 in a gaseous phase becomes a refrigerant flow at a high speed in a gas-liquid mixed state together with refrigerant 30 in a non-boiled liquid phase. Then, the refrigerant flow spreads on surfaces of grooves 22 formed on heat receiving plate 15 on a second space 19 side, and a thin film refrigerant layer is formed. The thin film refrigerant layer receives heat generated by heat generating element 4 so that cooling is performed through effective vaporization.

Here, a process of normal operation of cooling device 5 in heat receiver 7 is simply described. In the normal operation of cooling device 5, check valve 14 maintains a closed state during a period where vaporization of refrigerant 30 sealed in heat receiver 7 is continued. When vaporization of refrigerant 30 progresses in heat receiver 7 so that most of refrigerant 30 flows out to heat radiation passage 9 through outflow port 13, an internal pressure of heat receiver 7 becomes low so that check valve 14 is released. Then, new refrigerant 30 flows into first space 18 in heat receiver 7. Thereafter, a part of refrigerant 30 in first space 18 is boiled again. Refrigerant 30 becomes a gas-liquid mixed flow at a high speed together with refrigerant 30 in a non-boiled liquid phase, spreads on heat receiving plate 15 on the second space 19 side as the thin film refrigerant layer, and is vaporized by heat generated by heat generating element 4. Such series of process is repeated so that it is possible to realize cooling device 5 having extremely effective cooling performance.

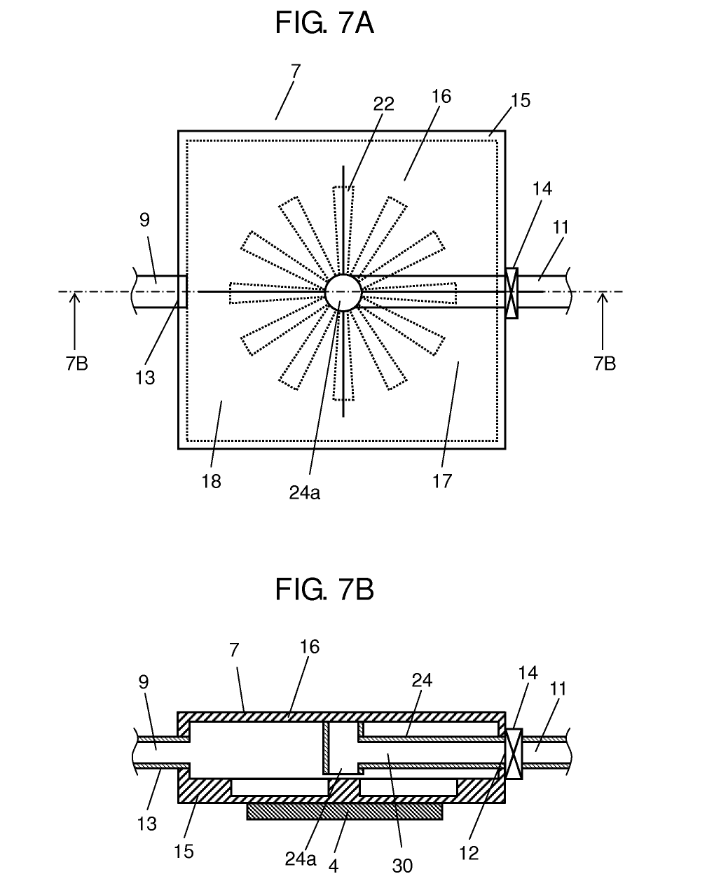

FIG. 7A is a plan view showing another heat receiver having high heat generation density of the cooling device according to the first exemplary embodiment of the present invention, and FIG. 7B is a cross-sectional view taken along line 7B-7B in FIG. 7A. As shown in FIG. 7A and FIG. 7B, outflow port 13 and inflow port 12 are provided to lateral wall surfaces of heat receiver 7. Introducing pipe 24 projects into the inside of heat receiving plate cover 16 from inflow port 12 through check valve 14. Introducing pipe 24 is characterized in that opening of introducing pipe 24 is directed to a center portion on a heat receiving plate 15 side. That is, introducing pipe 24 of return passage 11 extends to the center of heat receiving plate 15 from inflow port 12, and opening portion 24a of introducing pipe 24 is formed on the heat receiving plate 15 side. Introducing pipe 24 performs the same function as first space 18 of heat receiver 7 shown in FIG. 6A. Further, heat receiving plate 15 has grooves 22 which radially extend to peripheries of heat receiving plate 15 from opening portion 24a of introducing pipe 24. A cooling process of heat receiver 7 shown in FIG. 7A and FIG. 7B due to a phase change is substantially equal to a cooling process of heat receiver 7 shown in FIG. 6A due to a phase change.

That is, in an initial operation of cooling device 5 shown in FIG. 2A, the inside of heat receiver 7 is filled with refrigerant 30. Due to heat generated by heat generating element 4, boiling of refrigerant 30 dripped on heat receiving plate 15 from an end of introducing pipe 24 is started. Since a return passage 11 side is shut off by check valve 14, refrigerant 30 in a gaseous phase and refrigerant 30 in a non-boiled liquid phase in introducing pipe 24 flow into heat radiation passage 9 at a high speed so that the flow of refrigerant 30 is started. A force for driving refrigerant 30 is a pressure difference between a pressure in heat receiver 7 and a pressure in heat radiation unit 10 shown in FIG. 2A which is cooled by an outside air and is maintained at a low pressure.

At this point of time, firstly, refrigerant 30 on heat receiving plate 15 flows out to heat radiation passage 9 in heat receiver 7. Refrigerant 30 in introducing pipe 24 is shut off by check valve 14 and hence, a part of refrigerant 30 is boiled. Due to the volume expansion at the time, refrigerant 30 in a gaseous phase becomes a refrigerant flow at high speed in a gas-liquid mixed state together with refrigerant 30 in a non-boiled liquid phase. Then, the refrigerant flow spreads on surfaces of grooves 22 formed on heat receiving plate 15, and a thin film refrigerant layer is formed. The thin film refrigerant layer receives heat generated by heat generating element 4 so that cooling is performed by making use of effective vaporization.

Here, a process of normal operation of cooling device 5 in heat receiver 7 is simply described. In the normal operation of the cooling device, check valve 14 maintains a closed state during a period where vaporization of refrigerant 30 sealed in heat receiver 7 is continued. When vaporization of refrigerant 30 progresses in heat receiver 7 so that most of refrigerant 30 flows out to heat radiation passage 9 through outflow port 13, an internal pressure of heat receiver 7 becomes low and check valve 14 is released. Then, new refrigerant 30 flows into introducing pipe 24 in heat receiver 7. Thereafter, a part of refrigerant 30 in introducing pipe 24 is boiled again. Refrigerant 30 becomes a refrigerant flow at high speed together with refrigerant 30 in a non-boiled liquid phase, spreads on heat receiving plate 15 as the thin film refrigerant layer, and is vaporized by heat generated by heat generating element 4. Such series of process is repeated so that it is possible to realize cooling device 5 having extremely effective cooling performance.

Check valve 14 is provided to heat receiver 7 shown in FIG. 6A and FIG. 7A on which heat generating element 4 having high heat generation density is mounted. With respect to heat receiver 7 shown in FIG. 3A, FIG. 4A and FIG. 5A on which heat generating element 4 having relatively low heat generation density is mounted, heat receiver 7 on which heat generating element 4 having high heat generation density is mounted never fail to be disposed on an upstream side of a heat receiving unit.

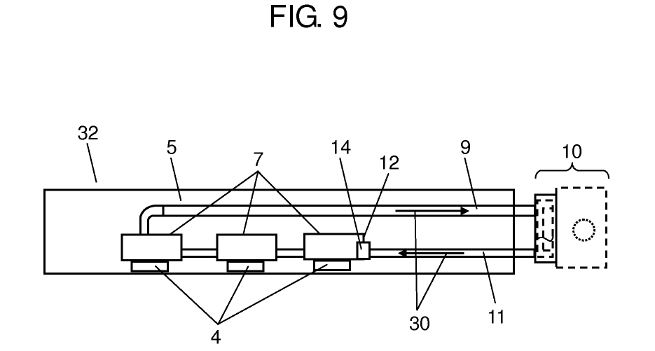

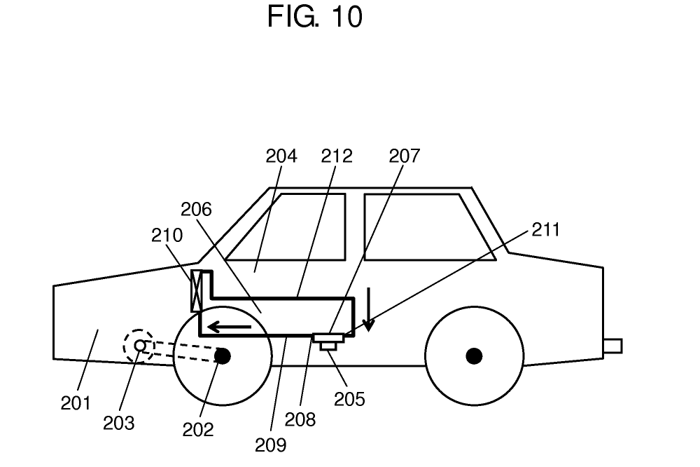

FIG. 9 is a schematic view of an electronic device according to the first exemplary embodiment of the present invention. In electronic device 32, cooling of high-speed arithmetic processor which configures heat generating element 4 is performed by cooling device 5. In cooling device 5, check valve 14 is provided on an inflow port 12 side of heat receiver 7 which is closest to return passage 11 among the plurality of heat receivers 7. Accordingly, a space ranging from a downstream side of check valve 14 to heat radiation unit 10, that is, spaces formed in the plurality of heat receivers 7 respectively and a space formed in heat radiation passage 9 configure one communication space. In the plurality of heat receivers 7 and the inside of heat radiation passage 9, a saturated vapor pressure of refrigerant 30 and a temperature of the saturated vapor become fixed values. As a result, respective heat receivers 7 can transfer the heat generated by heat generating elements 4 to refrigerant 30 under fixed conditions so that respective heat receivers 4 can ensure cooling performance irrespective of whether the heat receiver 4 is disposed at a front stage or at a rear stage.

### Second Exemplary Embodiment

FIG. 10 is a schematic view of an electric automobile according to a second exemplary embodiment of the present invention. As shown in FIG. 10, motor 203 which drives axle 202 of electric automobile 201 is connected to an inverter circuit (not shown) which configures a power converter mounted on cabin 204 of electric automobile 201.

As one example of a power semiconductor, the inverter circuit includes a plurality of semiconductor switching elements 205 which supply power to motor 203. Cooling device 206 which cools semiconductor switching element 205 is provided to the inverter circuit.

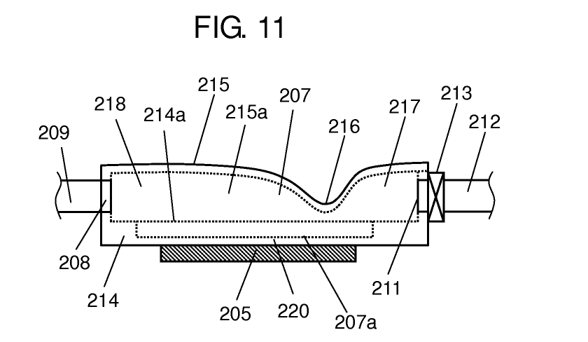

FIG. 11 is a front view showing a heat receiver of the cooling device according to the second exemplary embodiment of the present invention. As shown in FIG. 10 and FIG. 11, cooling device 206 includes: heat receiver 207; heat radiation unit 210; return passage 212; and check valve 213. In this exemplary embodiment, heat receiver 207 is connected to an upper surface of semiconductor switching element 205, and has inflow port 211 and discharge port 208. Heat radiation unit 210 is connected to discharge port 208 by way of heat radiation passage 209. Return passage 212 connects heat radiation unit 210 and inflow port 211 to each other. Check valve 213 is disposed in return passage 212.

A circulation passage made up of heat receiver 207, heat radiation passage 209, heat radiation unit 210, and return passage 212 forms a closed system, and an internal atmosphere of the circulation passage is held at a negative pressure which is lower than an atmospheric pressure.

Approximately several hundred cc of water is filled in such a negative pressure passage, for example. Water is one example of a refrigerant, and several hundred cc is an amount which is sufficiently small compared to a volume of the circulation passage.

That is, in the same manner as the cooling device disclosed in PTL 3, in cooling device 206 shown in FIG. 10, water in heat receiver 207 is firstly boiled due to heat generated by semiconductor switching element 205. Due to the increase in pressure at the time of boiling, water reaches heat radiation unit 210 through heat radiation passage 209 although water is in a gas-liquid mixed state. Next, when an outer surface of heat radiation unit 210 is cooled by air supplied by a fan (not shown), water is brought into a liquid phase state again. Thereafter, water is returned to return passage 212 upstream of check valve 213 shown in FIG. 11.

When water is returned to return passage 212 upstream of check valve 213 shown in FIG. 10, a pressure in heat receiver 207 is gradually lowered. When a pressure on an upstream side of check valve 213 which is mainly determined based on an amount of water becomes higher than the pressure in heat receiver 207, check valve 213 is released.

As a result, water on an upstream side of check valve 213 flows into the inside of heat receiver 207 and, then, water is explosively vaporized in heat receiver 207 instantaneously. Due to such heat of vaporization, semiconductor switching element 205 is effectively cooled.

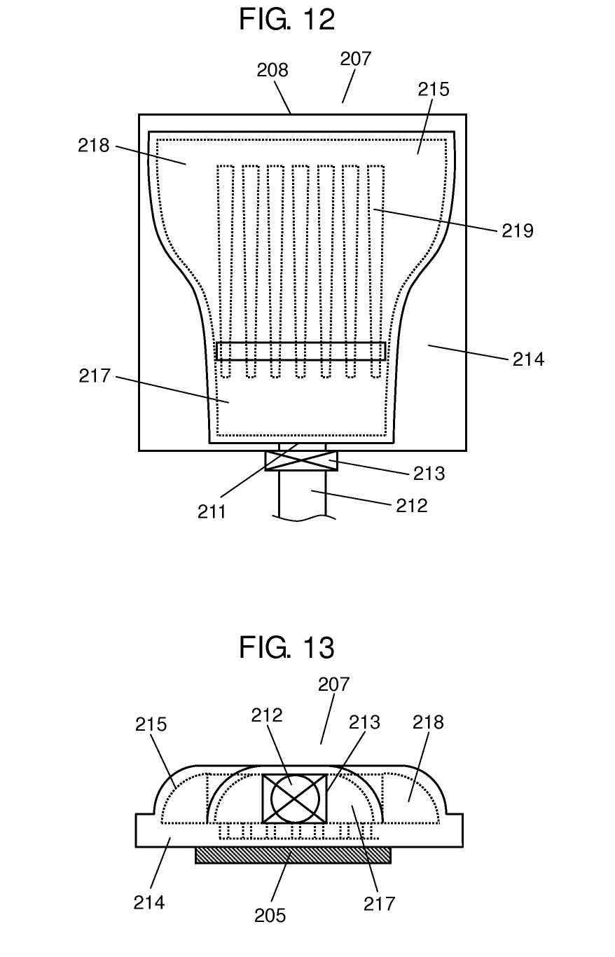

FIG. 12 is a plan view showing the heat receiver of the cooling device according to the second exemplary embodiment of the present invention, and FIG. 13 is a side view showing the heat receiver of the cooling device. As shown in FIG. 11 to FIG. 13, heat receiver 207 includes heat receiving plate 214 and heat receiving plate cover 215. Narrow opening forming portion 216 which lies close to heat receiving plate 214 side is disposed between discharge port 208 and inflow port 211 of heat receiving plate cover 215. In this exemplary embodiment, heat receiving plate 214 includes a heat absorbing portion 220 which absorbs heat by being brought into contact with a semiconductor switching element 205 which configures a heat generating element on a back surface side 207a of the heat receiver 207. Heat absorbing portion 220 is a portion which is in contact with semiconductor switching element 205. Heat absorbing portion 220 is disposed on a discharge port 208 side and on an inflow port 211 side respectively with narrow opening forming portion 216 interposed therebetween. Heat receiving plate cover 215 covers surface side 214a of heat receiving plate 214 with gap 215a formed between heat receiving plate cover 215 and surface side 214a of heat receiving plate 214.

At least one of discharge port 208 and inflow port 211 is formed in a lateral wall surface of heat receiver 207. As a result, a height of heat receiver 207 can be lowered.

By forming narrow opening forming portion 216 on heat receiving plate cover 215, first space 217 is formed in the heat receiver 207 on an inflow port 211 side and second space 218 is formed in the heat receiver 207 on a discharge port 208 side. First space 217 and second space 218 are connected to each other with narrow opening forming portion 216 interposed therebetween.

A volume of first space 217 on the inflow port 211 side is smaller than a volume of second space 218 on the discharge port 208 side.

Heat absorbing portion 220 is disposed such that heat absorbing portion 220 is connected to a discharge port 208 side of narrow opening forming portion 216, and is also connected to an inflow port 211 side of narrow opening forming portion 216. Heat absorbing portion 220 is also formed such that an area of heat absorbing portion 220 on the discharge port 208 side from narrow opening forming portion 216 is set larger than an area of heat absorbing portion 220 on the inflow port 211 side from narrow opening forming portion 216. Due to the provision of narrow opening forming portion 216, water in a thin film state rapidly spreads into second space 218 from first space 217 and hence, extremely high heat transmission efficiency can be acquired at heat absorbing portion 220 of heat receiving plate 214 so that cooling efficiency is also increased.

In the above-mentioned configuration, as shown in FIG. 11 to FIG. 13, check valve 213 is provided outside heat receiver 207. Return passage 212 is simply connected to inflow port 211 of heat receiver 207 without projecting into the inside of heat receiver 207. Due to such a configuration, it is unnecessary to determine the position to which an end of return passage 212 is inserted at the time of manufacturing heat receiver 207 so that the manufacturing of heat receiver 207 becomes simplified.

A volume of first space 217 formed in heat receiver 207 to which return passage 212 is connected is smaller than a volume of second space 218 formed in heat receiver 207.

Accordingly, as described above, when a pressure in heat receiver 207 is gradually lowered, and a pressure which is mainly determined based on an amount of water present on an upstream side of check valve 213 becomes higher than the pressure in heat receiver 207, check valve 213 is released. When water on an upstream side of check valve 213 flows into the inside of first space 217, part of water is boiled in first space 217 so that a pressure in first space 217 is rapidly increased.

At this stage of the operation, since first space 217 is set smaller than second space 218, compared to the case where first space 217 and second space 218 have the substantially same size, the increase in pressure in first space 217 becomes large. Water remaining in first space 217 vigorously enters second space 218 in the form of a thin film through narrow opening forming portion 216.

Second space 218 has large heat absorbing portion 220. Accordingly, water which enters second space 218 in a thin film state is rapidly vaporized. Due to the increase in pressure at this point of time, water reaches heat radiation unit 210 shown in FIG. 10 through heat radiation passage 209 although water is in a gas-liquid mixed state. Next, when an outer surface of heat radiation unit 210 is cooled by a fan (not shown), water is brought into a liquid phase state again and, thereafter, water is returned to the upstream side of check valve 213 disposed in return passage 212.

It is preferable that a plurality of grooves 219 are formed on a front surface of heat receiving plate 214 such that the grooves 219 extend over first space 217, narrow opening forming portion 216, and second space 218. That is, grooves 219 are formed on the front surface of heat receiving plate 214 such that grooves 219 extend toward a discharge port 208 side from an inflow port 211 side of narrow opening forming portion 216. Due to such a configuration, water in a thin film state easily spreads to second space 218 from first space 217 on the front surface of heat receiving plate 214 at part of second space 218 and hence, heat exchange efficiency becomes high.

By repeating such circulation, semiconductor switching element 205 can be sufficiently cooled.

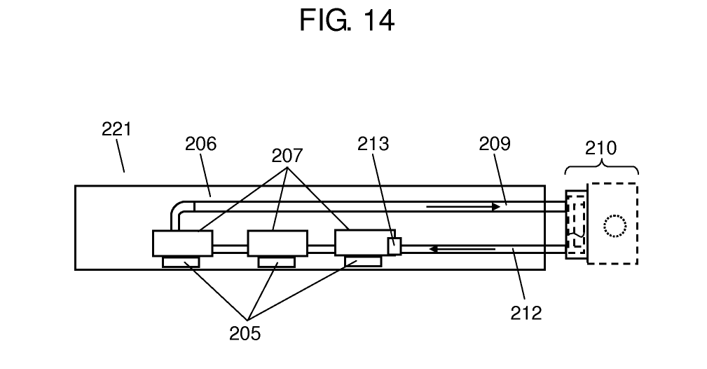

FIG. 14 is a schematic view of an electronic device according to the second exemplary embodiment of the present invention. In electronic device 221, cooling of semiconductor switching element 205 which is a heat generating element is performed by cooling device 206. As shown in FIG. 11, since narrow opening forming portion 216 which lies close to a heat receiving plate 214 side is provided between discharge port 208 and inflow port 211 of heat receiving plate cover 215, a flow speed of water is increased when water passes through narrow opening forming portion 216 so that water is formed into a thin film shape. Accordingly, as shown in FIG. 14, it becomes unnecessary to extend an end of return passage 212 to the inside of heat receiver 207, and it is also unnecessary to adjust the position of an end of return passage 212.

### Third Exemplary Embodiment

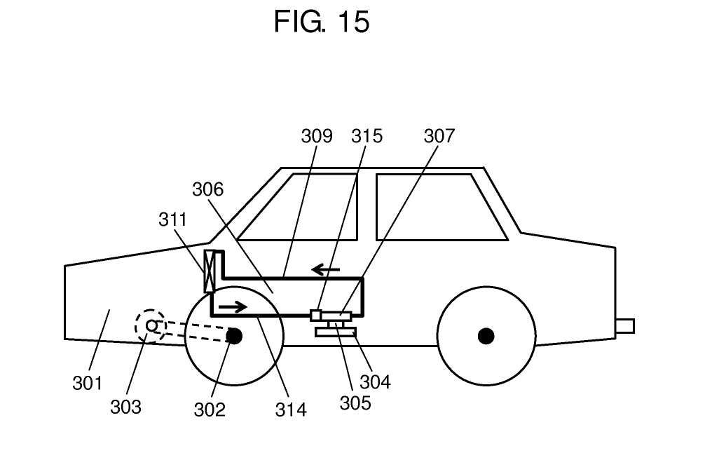

FIG. 15 is a schematic view of an electric automobile according to a third exemplary embodiment of the present invention. As shown in FIG. 15, motor 303 which drives axle 302 of electric automobile 301 is connected to inverter circuit 304 which configures a power converter mounted on electric automobile 301.

Inverter circuit 304 includes a plurality of semiconductor switching elements 305 which supply power to motor 303. Semiconductor switching element 305 is one example of a power semiconductor. A heating value of semiconductor switching element 305 is large so that semiconductor switching element 305 is cooled by cooling device 306.

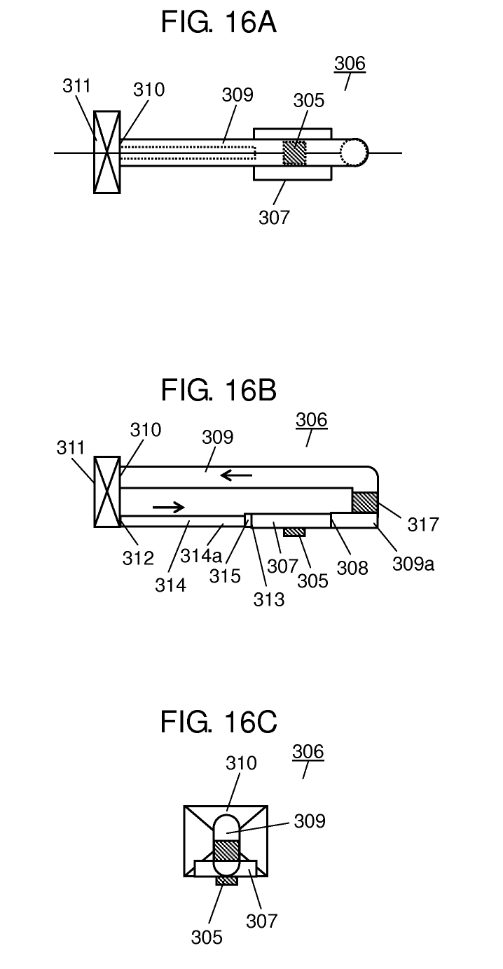

FIG. 16A is a plan view showing the first configuration of the cooling device according to the third exemplary embodiment of the present invention, FIG. 16B is a front view of the cooling device shown in FIG. 16A, and FIG. 16C is a side view of the cooling device shown in FIG. 16A.

As shown in FIG. 16A to FIG. 16C, cooling device 306 includes: heat receiver 307; heat radiation passage 309; heat radiating unit 311; return passage 314; and check valve 315. In this exemplary embodiment, box-shaped heat receiver 307 is in contact with an upper surface of a semiconductor switching element 305 in a heat conductive manner. Heat receiver 307 has inflow port 313 and discharge port 308. Water which is a refrigerant flows into heat receiver 307 through inflow port 313, and water flows out from heat receiver 307 through discharge port 308. Heat radiating unit 311 has inflow portion 310 and outflow portion 312. Water flows into heat radiating unit 311 through inflow portion 310, and water flows out from heat radiating unit 311 through outflow portion 312.

Heat radiating unit 311 and heat receiver 307 are connected to each other by way of heat radiation passage 309 and return passage 314. Heat radiation passage 309 connects discharge port 308 and inflow portion 310 to each other. Return passage 314 connects outflow portion 312 and inflow port 313 to each other. Check valve 315 is disposed in return passage 314 such that check valve 315 is disposed adjacent to inflow port 313. Inflow portion 310 is disposed above outflow portion 312.

To be more specific, heat receiver 307, heat radiation passage 309, heat radiating unit 311, return passage 314, check valve 315 and heat receiver 307 configure an annular passage. When water is used as one example of a refrigerant, an amount of water smaller than a volume of the circulation passage is sealed in the annular passage, and cooling device 306 is used in a state where a pressure in the annular passage is maintained at a pressure lower than an atmospheric pressure.

By releasing check valve 315, water on an upstream side of check valve 315, that is, water in return passage 314 flows into the inside of heat receiver 307. Next, water receives heat from semiconductor switching elements 305 in heat receiver 307 so that the water is rapidly boiled. Heat of semiconductor switching elements 305 is absorbed in this manner so that semiconductor switching element 305 is cooled.

Water is boiled in heat receiver 307 and hence, a pressure in heat receiver 307 is rapidly increased. As a result, check valve 315 is closed, and water in heat receiver 307 in a gas-liquid mixed phase state flows into heat radiating unit 311 from discharge port 308 of heat receiver 307 through heat radiation passage 309. Thereafter, vapor in heat radiating unit 311 is condensed due to air supplied to a surface of heat radiating unit 311 so that the vapor is brought into a liquid state again, and is returned to an upstream side of check valve 315.

In cooling device 306 having such a configuration, to release check valve 315 which is closed once, it is necessary that a pressure on an upstream side of check valve 315 becomes larger than a pressure on a downstream side of check valve 315, that is, a pressure in heat receiver 307. For this end, it may be possible to adopt a method where a height of a portion on an upstream side of check valve 315, that is, a height of a portion on a return passage 314 side is increased so as to increase a head pressure of water accumulated in return passage 314. However, when such a method is used, it is difficult to reduce a height of cooling device 306.

In view of the above, in this exemplary embodiment, a cross-sectional area of discharge-port connection pipe passage 309a of heat radiation passage 309 which is connected to discharge port 308 is set larger than a cross-sectional area of inflow-port connection pipe passage 314a of return passage 314 which is connected to inflow port 313. That is, a pipe diameter of discharge-port connection pipe passage 309a is set larger than a pipe diameter of inflow-port connection pipe passage 314a. As a result, a pipe pressure loss in heat radiation passage 309 can be suppressed as much as possible. Discharge-port connection pipe passage 309a includes raised portion 317 which is raised upward from the discharge port 308.

As a result, the pressure increase in heat receiver 307 from a pressure at the time of releasing check valve 315 becomes small and hence, check valve 315 can be released even when a head pressure of water accumulated in return passage 314 is low. Accordingly, it is possible to reduce a height of cooling device 306.

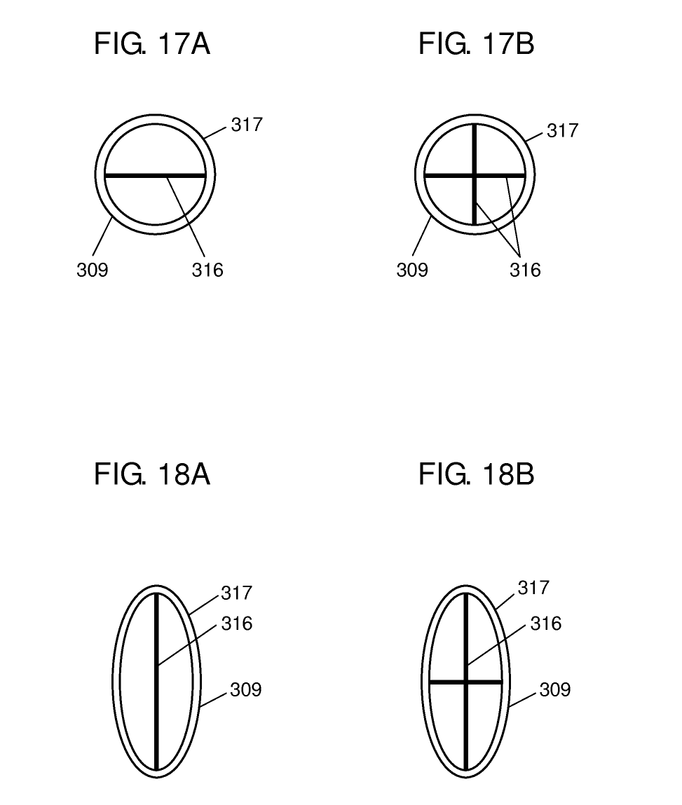

FIG. 17A is a plan view showing a first heat radiation passage of the cooling device according to the third exemplary embodiment of the present invention, and FIG. 17B is a plan view showing a second heat radiation passage of the cooling device. As shown in FIG. 17A and FIG. 17B, raised portion 317 includes dividing body 316 where a cross section of raised portion 317 is divided into a plurality of sections. The cross section of raised portion 317 is divided into two in FIG. 17A, and the cross section of raised portion 317 is divided into four in FIG. 17B. As a result, water in a gas-liquid mixed phase state can be smoothly circulated to a heat radiating unit 311 side shown in FIG. 16B. The smooth circulation of water is important for reducing a height of cooling device 306.

That is, water in a liquid phase state is heavy and hence, at raised portion 317 disposed downstream of discharge port 308 of heat receiver 307 shown in FIG. 16B, water flows toward a heat radiating unit 311 side and rises up in heat radiation passage 309. However, there is the case where a water backflow phenomenon (flooding phenomenon) occurs where water falls at a certain point and returns to the inside of heat receiver 307 again.

A flooding phenomenon is simply described below. Usually, water in a gas-liquid mixed phase state which receives heat is originally expected such that water speedily moves toward a heat radiating unit 311 side shown in FIG. 16B where a pressure is low from a heat receiver 307 side shown in FIG. 16B where a pressure is high and returns to heat receiver 307 after heat radiation. However, when a pipe passage having a large cross-sectional area is used, water in a gas-liquid mixed state which receives heat is once pushed up to a high position from a low position due to a high pressure on a heat receiver 307 side. However, when a diameter of the pipe passage is large, there arises a phenomenon where a liquid surface which is formed by surface tension of a liquid phase is not maintained so that the whole water flows backward. Such a phenomenon is referred to as a flooding phenomenon. As a result, water which receives heat does not reach heat radiating unit 311, and stagnates in an intermediate portion of heat radiation passage 309. When the flooding phenomenon continues, heat is accumulated on a heat receiver 307 side, and becomes a cause of remarkable lowering of original cooling performance.

In view of the above, dividing body 316 where a cross-sectional area of heat radiation passage 309 is divided into a plurality of sections is provided to heat radiation passage 309, particularly, to raised portion 317 disposed downstream of discharge port 308 of heat receiver 307. Such dividing body 316 makes water in a liquid phase adhere to a wall surface configuring dividing body 316 so that a meniscus is maintained. Accordingly, water can easily rise in raised portion 317 of heat radiation passage 309. Water which reaches heat radiating unit 311 is used for heat radiation and, the whole water is brought into a liquid phase, after heat radiation, and returns to an upstream side of check valve 315. Accordingly, the stable circulation of water is ensured.

Further, dividing body 316 increases a contact length with water and hence, a pressure loss is generated in the passage. However, a length of dividing body 316 per se is extremely short and hence, dividing body 316 minimally influences a head pressure whereby no problems arise.

A cross-sectional shape of raised portion 317 is a circular shape.

FIG. 18A is a plan view showing a third heat radiation passage of the cooling device according to the third exemplary embodiment of the present invention, and FIG. 18B is a plan view showing a fourth heat radiation passage of the cooling device. As shown in FIG. 18A and FIG. 18B, a cross-sectional shape of raised portion 317 may be an elliptical shape. It may be possible to provide dividing body 316 shown in FIG. 18A where the cross section of heat radiation passage 309 shown in FIG. 16B is divided into two sections. It may be also possible to provide dividing body 316 shown in FIG. 18B where the cross section of heat radiation passage 309 shown in FIG. 16B is divided into four sections. Whether a cross section of heat radiation passage 309 is to be divided into two sections or into four sections may be determined depending on a diameter and a length of a passage to which dividing body 316 is provided.

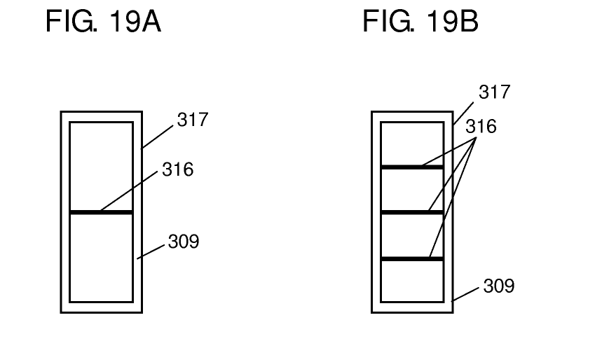

FIG. 19A is a plan view showing a fifth heat radiation passage of the cooling device according to the third exemplary embodiment of the present invention, and FIG. 19B is a plan view showing a sixth heat radiation passage of the cooling device. As shown in FIG. 19A and FIG. 19B, a cross-sectional shape of raised portion 317 may be a quadrangular shape. Dviding body 316 where a cross section of heat radiation passage 309 shown in FIG. 16B is divided into two sections as shown in FIG. 19A may be provided to raised portion 317, or dividing body 316 where a cross section of heat radiation passage 309 shown in FIG. 16B is divided into four sections shown in FIG. 19B may be provided to raised portion 317.

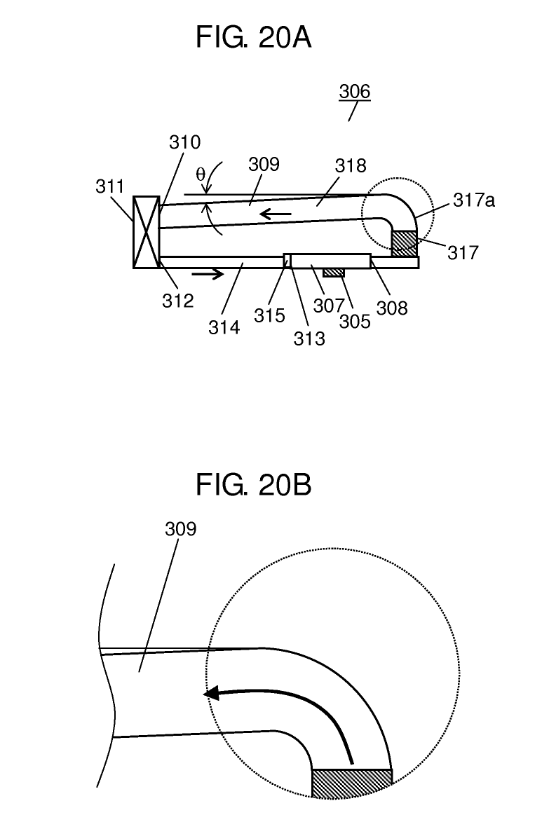

FIG. 20A is a front view showing the second configuration of the cooling device according to the third exemplary embodiment of the present invention, and FIG. 20B is a view showing an essential part of the heat radiation passage shown in FIG. 20A. As shown in FIG. 20A and FIG. 20B, upper end 317a of raised portion 317 is positioned above inflow portion 310. Any one of dividing bodies 316 shown in FIG. 17A to FIG. 19B where a cross section of heat radiation passage 309 is divided into a plurality of sections is provided to raised portion 317. Heat radiation passage 309 ranging from raised portion end 317a to inflow portion 310 is formed of inclined passage 318 inclined horizontally downward at an inclination angle θ.

That is, water in a liquid phase state adheres to heat radiation passage 309 having dividing body 316, and is lifted up to a position above inflow portion 310 due to a pressure from heat receiver 307. Thereafter, water is surely conveyed to a heat radiating unit 311 side through inclined passage 318. As a result, a stable circulation is performed in cooling device 306 so that cooling device 306 exhibits high cooling performance even when a height of cooling device 306 is reduced.

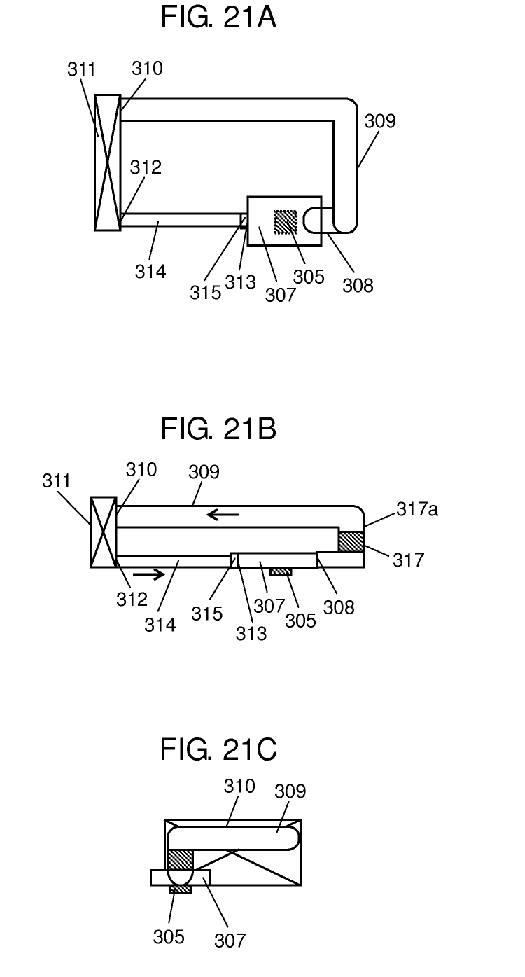

FIG. 21A is a plan view showing the third configuration of the cooling device according to the third exemplary embodiment of the present invention, FIG. 21B is a front view of the cooling device shown in FIG. 21A, and FIG. 21C is a side view of the cooling device shown in FIG. 21A. As shown in FIG. 21A to FIG. 21C, inflow portion 310 is positioned above outflow portion 312. Raised portion 317 which extends upward from discharge port 308 is provided to heat radiation passage 309. Any one of dividing bodies 316 shown in FIG. 17A to FIG. 19B is provided to raised portion 317. Heat radiation passage 309 is bent in the horizontal direction from raised portion end 317a, and is connected to inflow portion 310.

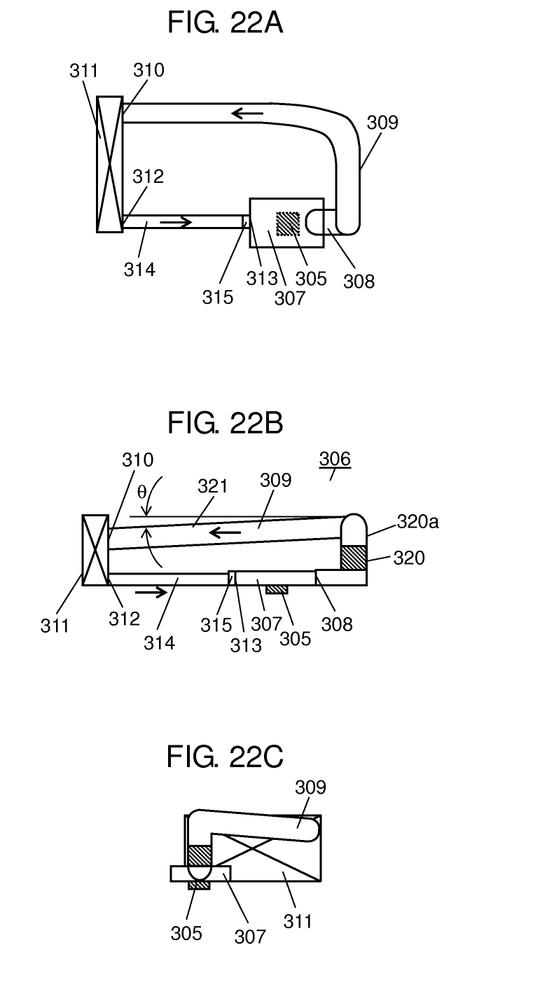

FIG. 22A is a plan view showing the fourth configuration of the cooling device according to the third exemplary embodiment of the present invention, FIG. 22B is a front view of the cooling device shown in FIG. 22A, and FIG. 22C is a side view of the cooling device shown in FIG. 22A. As shown in FIG. 22A to FIG. 22C, inflow portion 310 of heat radiating unit 311 is positioned above outflow portion 312. Raised portion 320 which extends upward from discharge port 308 is provided to heat radiation passage 309. Any one of dividing bodies 316 shown in FIG. 17A to FIG. 19B is provided to raised portion 320. Heat radiation passage 309 is bent in the horizontal direction from raised portion end 320a, and is connected to inflow portion 310.

In this exemplary embodiment, raised portion 320 is raised higher than inflow portion 310. Heat radiation passage 309 which extends to inflow portion 310 from raised portion upper end 320a is formed of inclined passage 321 inclined horizontally downward at an inclination angle θ.

That is, water in a liquid phase state adheres to heat radiation passage 309 having dividing body 316, and is lifted up to a position above inflow portion 310 due to a pressure from heat receiver 307. Thereafter, water is surely conveyed to a heat radiating unit 311 side through inclined passage 321. As a result, a stable circulation is performed in cooling device 306 so that cooling device 306 exhibits high cooling performance even when a height of cooling device 306 is reduced.

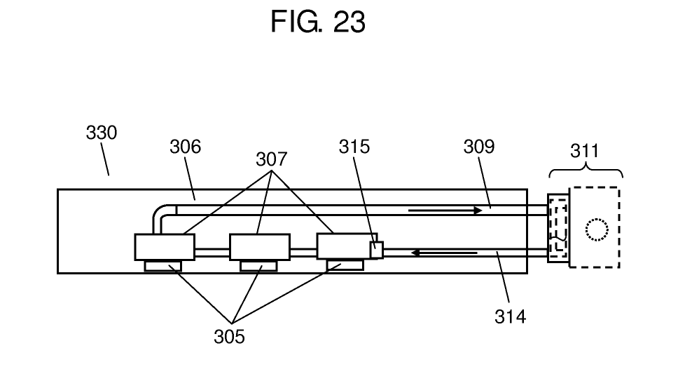

FIG. 23 is a schematic view of an electronic device according to the third exemplary embodiment of the present invention. In electronic device 330, cooling of semiconductor switching element 305 which configures a heat generating element is performed by cooling device 306. Cooling device 306 whose height is reduced can be easily mounted even on electronic device 330 which is integrated at a high density.

### INDUSTRIAL APPLICABILITY

The cooling device of the present invention is effectively applicable to a power converter of an electric automobile, and a high-speed arithmetic processor of an electronic device.

### REFERENCE MARKS IN THE DRAWINGS

1, 201, 301 electric automobile
2, 202, 302 axle
3, 203, 303 motor
4, 4a, 4b, 4c, 4d, 104 heat generating element
5, 206, 306 cooling device
6 power converter
7, 107, 207, 307 heat receiver
7a tubular heat receiver
8, 108 heat receiving unit
9, 109, 209, 309 heat radiation passage
10, 110, 210, 311 heat radiating unit
11, 111, 212, 314 return passage
12, 112, 211, 313 inflow port
13, 113 outflow port
14, 213, 315 check valve
15, 214 heat receiving plate
15a, 214a surface side
16, 215 heat receiving plate cover
18, 217 first space
19, 218 second space
22, 219 groove
23, 216 narrow opening forming portion
24 introducing pipe
24a opening portion
30 refrigerant
31, 220 heat absorbing portion
32, 221, 330 electronic device
117 refrigerant driving pump
204 cabin
205, 305 semiconductor switching element
207a back surface side
208, 308 discharge port
215a gap
304 inverter circuit
309a discharge-port connection pipe passage
310 inflow portion
312 outflow portion
314a inflow-port connection pipe passage
316 dividing body
317, 320 raised portion
317a, 320a raised portion upper end
318, 321 inclined passage

1. A cooling device comprising:
a heat receiving unit which absorbs heat generated by a heat generating element and transfers the heat (generated by the heat generating element) to a refrigerant;
a heat radiation unit which radiates the heat of the refrigerant; and
a heat radiation passage and a return passage which connect the heat receiving unit and the heat radiation unit,
the cooling device performing cooling by making use of a phase change between a liquid phase and a gaseous phase of the refrigerant by circulating the refrigerant through the heat receiving unit, the heat radiation passage, the heat radiation unit, the return passage, and the heat receiving unit,
wherein the heat receiving unit is configured by placing in series a plurality of heat receivers each of which has an inflow port and an outflow port for the refrigerant, and a check valve is provided on an inflow port side of a heat receiver which is closest to the return passage among the plurality of heat receivers.

2. The cooling device according to claim 1, wherein a check valve is further provided on an inflow port side of each of the plurality of heat receivers besides the heat receiver which is closest to the return passage.

3. The cooling device according to claim 1, wherein the plurality of heat receivers are tubular heat receivers when heat density of the heat generating element is less than 20 W/cm².

4. The cooling device according to claim 1, wherein when heat density of the heat generating element is 20 W/cm² or more, each of the plurality of heat receivers includes a heat receiving plate having a heat absorbing portion and a heat receiving plate cover which covers a vaporizing space for vaporizing the refrigerant on a front surface side of the heat receiving plate, a narrow opening forming portion which reduces a cross section of a passage for the refrigerant is provided between the outflow port and the inflow port, and
the heat absorbing portion is disposed from an outflow port side to an inflow port side across the narrow opening forming portion.

5. The cooling device according to claim 4, wherein an introducing pipe of the return passage extends to a center of the heat receiving plate from the inflow port, and an opening portion of the introducing pipe is formed on a heat receiving plate side.

6. An electric automobile comprising the cooling device of claim 1 for cooling the heat generating element.

7. An electric device comprising the cooling device of claim 1 for cooling the heat generating element.

8. A cooling device comprising:
a heat receiver having an inflow port and a discharge port;
a heat radiation unit connected to the discharge port by way of a heat radiation passage;
a return passage which connects the heat radiation unit and the inflow port; and
a check valve disposed in the return passage,
wherein the heat receiver includes:
a heat receiving plate having a heat absorbing portion on a back surface side, the heat absorbing portion being in contact with a heat generating element for absorbing heat; and
a heat receiving plate cover which covers a front surface side of the heat receiving plate with a gap formed therebetween,
the heat receiving plate cover is provided with a narrow opening forming portion which lies close to the heat receiving plate between the discharge port and the inflow port, and
the heat absorbing portion is disposed from a discharge port side to an inflow port side across the narrow opening forming portion.

9. The cooling device according to claim 8, wherein a volume of a first space disposed on the inflow port side of the narrow opening forming portion is smaller than a volume of a second space disposed on the discharge port side of the narrow opening forming portion.

10. The cooling device according to claim 8, wherein at least one of the discharge port and the inflow port is disposed lateral to the heat receiver.

11. The cooling device according to claim 8, wherein a groove is formed on a surface of the heat receiving plate, the groove extending toward the discharge port side from the inflow port side of the narrow opening forming portion.

12. An electric automobile comprising the cooling device of claim 8 for cooling the heat generating element.

13. An electric device comprising the cooling device of claim 8 for cooling a heat generating element.

14. A cooling device comprising:
a heat receiver having an inflow port and a discharge port;
a heat radiation unit having an inflow portion and an outflow portion;
a heat radiation passage which connects the discharge port and the inflow portion;
a return passage which connects the outflow portion and the inflow port; and
a check valve disposed in the return passage,
wherein the inflow portion is disposed above the outflow portion, and a discharge-port connection pipe passage of the heat radiation passage which is connected to the discharge port has a larger cross-sectional area than a cross-sectional area of an inflow-port connection pipe passage of the return passage which is connected to the inflow port.

15. The cooling device according to claim 14, wherein the discharge-port connection pipe passage includes a raised portion which is raised upward from the discharge port, and a dividing body disposed in the raised portion to divide a cross section of the raised portion into a plurality of sections.

16. The cooling device according to claim 15, wherein an upper end of the raised portion is positioned above the inflow portion.

17. The cooling device according to claim 16, wherein the heat radiation passage ranging from the upper end of the raised portion to the inflow portion is an inclined passage which is inclined horizontally downward.

18. The cooling device according to claim 15, wherein a cross-sectional shape of the raised portion is a circular shape or a quadrangular shape.

19. An electric automobile comprising the cooling device of claim 14 for cooling a heat generating element.

20. An electric automobile comprising the cooling device of claim 14 for cooling a heat generating element.
